(19) United States
(12) Patent Application Publication
(10) Pub. No.: US 2026/0231759 A1
(43) Pub. Date: Aug. 6, 2026

(54) INSULATION SIGNAL TRANSMISSION ELEMENT AND SEMICONDUCTOR DEVICE

(71) Applicant: ROHM Co., LTD., Kyoto (JP)

(72) Inventor: Hiroaki Matsubara, Kyoto (JP)

(21) Appl. No.: 19/456,903

(22) Filed: Jan. 22, 2026

(30) Foreign Application Priority Data
Jan. 24, 2025 (JP) 2025-010326

(51) Int. Cl. H10W 29/00; H01F 27/28

(52) U.S. Cl. CPC H10W 29/00; H01F 27/2804; H01F 2027/2809

(57) ABSTRACT

Provided is an insulation signal transmission element including a plurality of insulation layers stacked in a thickness direction and a magnetic field coupling part including a first coil positioned on a first side of the thickness direction and a second coil positioned on a second side of the thickness direction. The plurality of insulation layers include at least one first insulation layer interposed between the first coil and the second coil in the thickness direction, and each of the insulation layers includes glass fibers.

### PRIORITY

The present disclosure contains subject matter related to that disclosed in Japanese Priority Patent Application JP 2025-010326 filed in the Japan Patent Office on January 24, 2025, the entire content of which is hereby incorporated by reference.

### BACKGROUND

The present disclosure relates to an insulation signal transmission element and a semiconductor device.

For example, Japanese Patent Laid-open No. 2024-144569 discloses a semiconductor device for use in electric vehicles or hybrid electric vehicles. The disclosed semiconductor device includes a first semiconductor element, a second semiconductor element, and an insulation element. The first and second semiconductor elements transmit signals via the insulation element. The insulation element permits transmission of electric signals in an insulated state through magnetic field coupling of two inductors (coils).

### BRIEF DESCRIPTION OF THE DRAWINGS

FIG. 1 is a plan view depicting a semiconductor device in a first embodiment of the present disclosure;

FIG. 2 is a view depicting a sealing resin delineated by imaginary lines in the plan view of FIG. 1;

FIG. 3 is a front view of the semiconductor device in the first embodiment;

FIG. 4 is a left view of the semiconductor device in the first embodiment;

FIG. 5 is a right view of the semiconductor device in the first embodiment;

FIG. 6 is a sectional view taken on line VI-VI in FIG. 2;

FIG. 7 is a main part enlarged sectional view that enlarges parts in FIG. 6;

FIG. 8 is a sectional view taken on line VIII-VIII in FIG. 2;

FIG. 9 is a schematic plan view depicting an insulation signal transmission element in the first embodiment;

FIG. 10 is a sectional view taken on line X-X in FIG. 9;

FIG. 11 is a detail view depicting an insulation signal transmission element insulation layer in the first embodiment;

FIG. 12 is a sectional view depicting a first modification of the insulation signal transmission element in the first embodiment;

FIG. 13 is a sectional view depicting a second modification of the insulation signal transmission element in the first embodiment;

FIG. 14 is a sectional view depicting a third modification of the insulation signal transmission element in the first embodiment; and

FIG. 15 is a sectional view depicting a fourth modification of the insulation signal transmission element in the first embodiment.

### DETAILED DESCRIPTION

Some preferred embodiments of the present disclosure will be described below in detail with reference to the accompanying drawings.

In the description that follows, the ordinal notations such as “first,” “second,” and “third” are provided only for identification of objects and do not necessarily limit or determine the sequence of these objects.

In the present disclosure, the wordings “object A is formed in object B” and “object A is formed on object B” signify, unless otherwise noted, that “object A is formed directly in or on object B” and that “object A is formed in or on object B with some other object interposed therebetween.” Similarly, the wordings “object A is arranged in object B” and “object A is arranged on object B” signify, unless otherwise noted, that “object A is arranged directly in or on object B” and that “object A is arranged in or on object B with some other object interposed therebetween.” Likewise, the wording “object A is positioned on object B” signifies, unless otherwise noted, that “object A is in contact with and positioned on object B” and that “object A is positioned on object B with some other object interposed therebetween.” Further, the wording “object A overlaps with object B when viewed in a given direction” signifies, unless otherwise noted, that “object A overlaps with the entire object B” and that “object A overlaps partially with object B.” Also in this disclosure, the state expressed by the wording “surface A faces direction B (on one side or on the other side thereof)” is not limited to the case where surface A is at an angle of 90 degrees with respect to direction B, and includes cases where surface A is inclined relative to direction B.

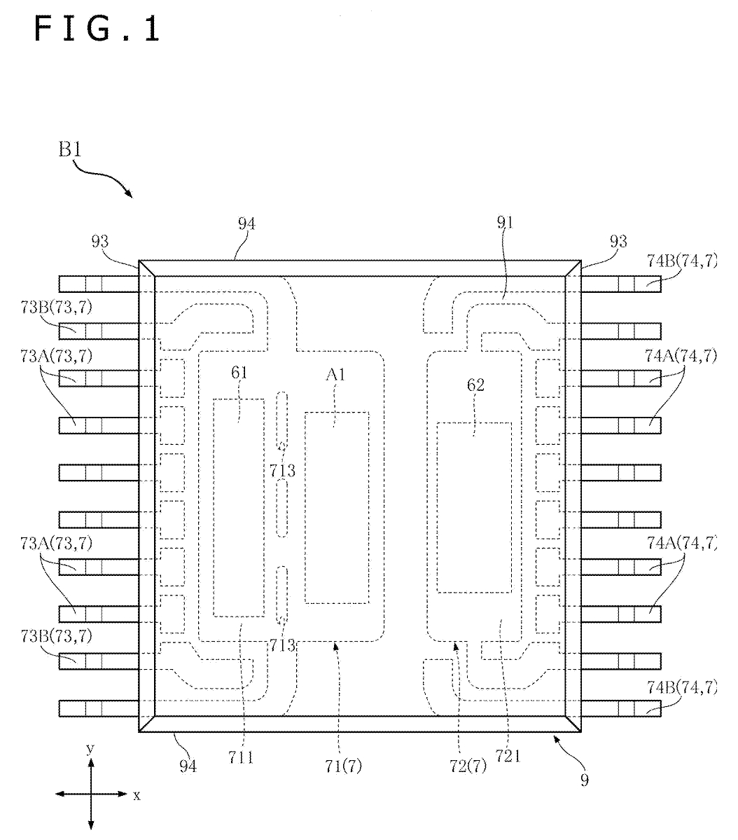

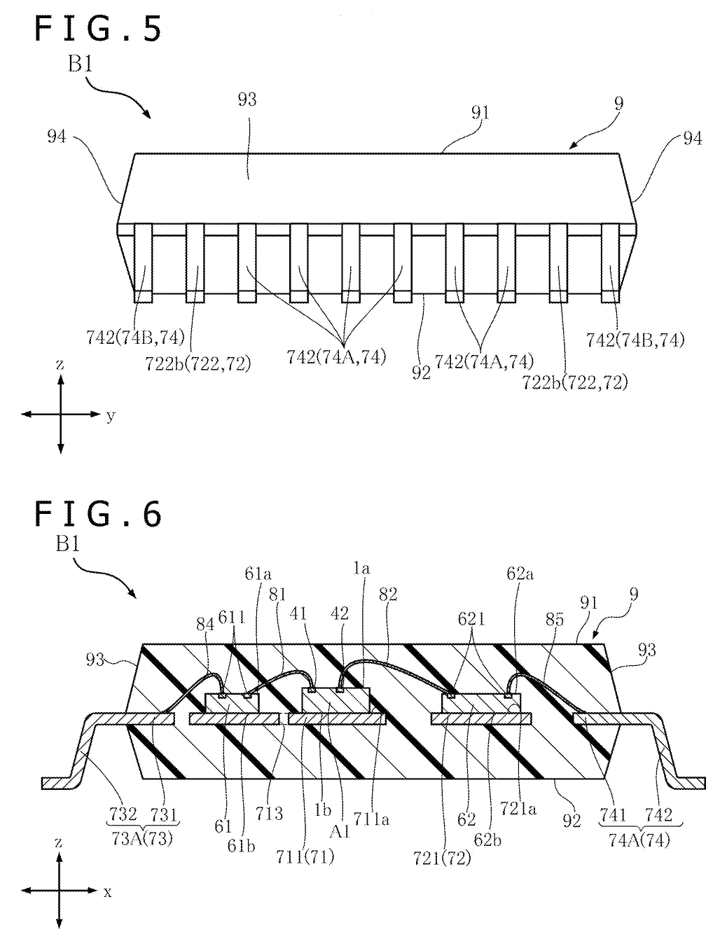

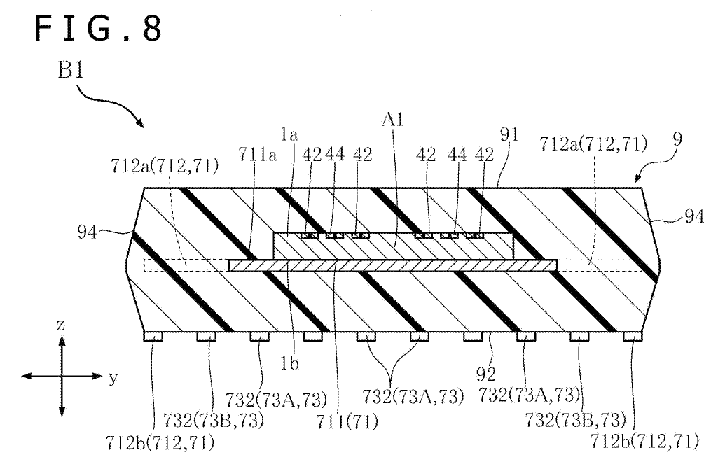

FIGS. 1 through 11 depict a semiconductor device B1 in a first embodiment of the present disclosure. As indicated in these drawings, the semiconductor device B1 includes a plurality of insulation signal transmission elements A1, a first semiconductor element 61, a second semiconductor element 62, a conductive support 7, a plurality of connection members 8, and a sealing resin 9. The conductive support 7 includes a plurality of leads 71 through 74. The plurality of connection members 8 include a plurality of wires 81, 82, and 84 through 87.

In these drawings, the direction of thicknesses in the present disclosure is defined as a thickness direction z. A first side of the thickness direction z is referred to as a z1 side, and the opposite side to the first side of the z direction is referred to as a z2 side. A direction perpendicular to the thickness direction z is defined as a first direction x. A direction perpendicular to the thickness direction z and the first direction x is defined as a second direction y.

The semiconductor device B1 is used in electric vehicles or hybrid electric vehicles, for example. The semiconductor device B1 controls switching operations of switching elements such as insulated gate bipolar transistors (IGBTs) or metal oxide semiconductor field effect transistors (MOSFETs). The package type of the semiconductor device B1 is a Small Outline Package (SOP), as can be seen in FIGS. 1 and 3 through 5. It is to be noted that the package type of the semiconductor device B1 is not limited to the SOP.

The first semiconductor element 61 is a controller (control element) of a gate driver that drives switching elements such as IGBTs or MOSFETs. The first semiconductor element 61 has a circuit that converts a control signal input typically from an electronic control unit (ECU) into a pulse width modulation (PWM) control signal, a transmission circuit that transmits the PWM control signal to the insulation signal transmission element A1, and a reception circuit that receives electric signals from the insulation signal transmission element A1.

As depicted in FIG. 6, the first semiconductor element 61 has a principal surface 61a and a back surface 61b. The principal surface 61a and the back surface 61b are separated from each other in the thickness direction z. The principal surface 61a is an upper surface of the first semiconductor element 61, and the back surface 61b is a lower surface of the first semiconductor element 61. The back surface 61b faces the lead 71.

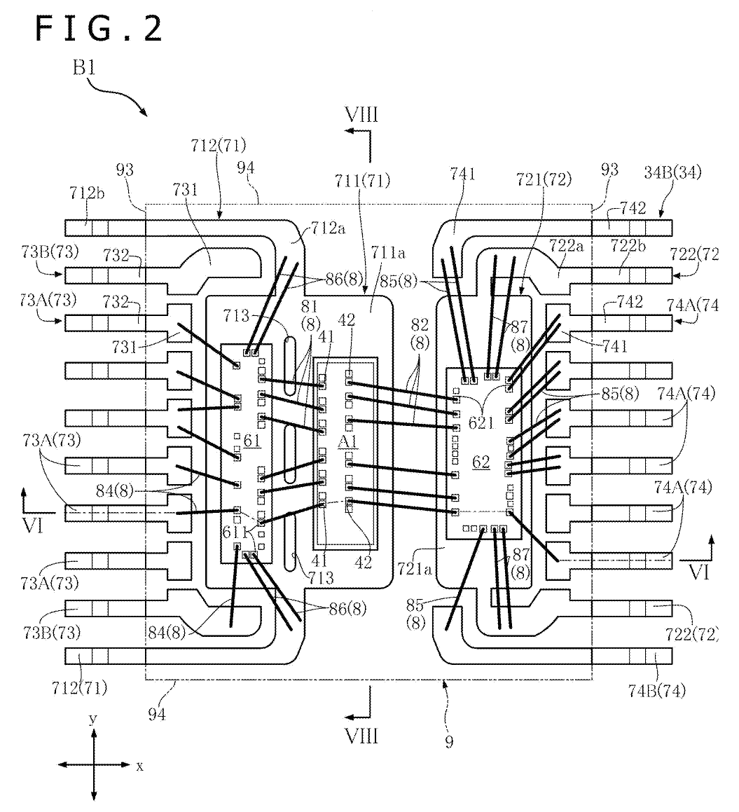

As depicted in FIGS. 2 and 6, the first semiconductor element 61 has a plurality of pads 611. The plurality of pads 611 are disposed on the principal surface 61a (i.e., a surface facing the same direction as a mounting surface 711a of an island part 711 of the lead 71, to be discussed later). The composition of each of the plurality of pads 611 includes copper (Cu), for example.

The second semiconductor element 62 is a gate driver (driver element) for driving switching elements. The second semiconductor element 62 has a reception circuit that receives the PWM control signal, a circuit that drives the switching element on the basis of the PWM control signal, and a transmission circuit that transmits an electric signal to the first semiconductor element 61. The electric signal may be an output signal from a temperature sensor disposed near a motor, for example.

As depicted in FIG. 6, the second semiconductor element 62 has a principal surface 62a and a back surface 62b. The principal surface 62a and the back surface 62b are separated from each other in the thickness direction z. The principal surface 62a is an upper surface of the second semiconductor element 62, and the back surface 62b is a lower surface of the second semiconductor element 62. The back surface 62b faces the lead 72.

As depicted in FIGS. 2 and 6, the second semiconductor element 62 has a plurality of pads 621. The plurality of pads 621 are disposed on the principal surface 62a (i.e., a surface facing the same direction as a mounting surface 721a of an island part 721 of the lead 72, to be discussed later). The composition of each of the plurality of pads 621 includes copper (Cu), for example.

The insulation signal transmission element A1 is an element (insulation element) that transmits the PWM control signal and other electric signals in an insulated state. The insulation signal transmission element A1 is of an inductive type. An example of the inductive type insulation signal transmission element A1 is an isolation transformer.

As depicted in FIGS. 6 through 10, the insulation signal transmission element A1 has a principal surface 1a and a back surface 1b. The principal surface 1a and the back surface 1b are separated from each other in the thickness direction z. The principal surface 1a is an upper surface of the insulation signal transmission element A1, and the back surface 1b is a lower surface of the insulation signal transmission element A1. The back surface 1b faces the lead 71.

The insulation signal transmission element A1 includes a plurality of insulation layers 1 and a magnetic field coupling part 2.

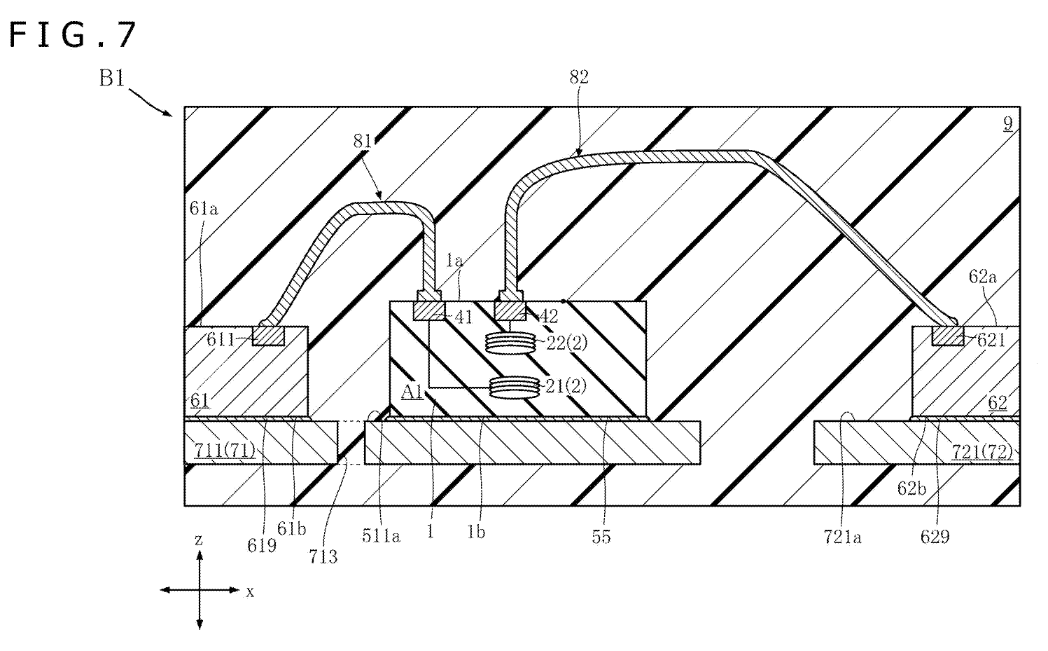

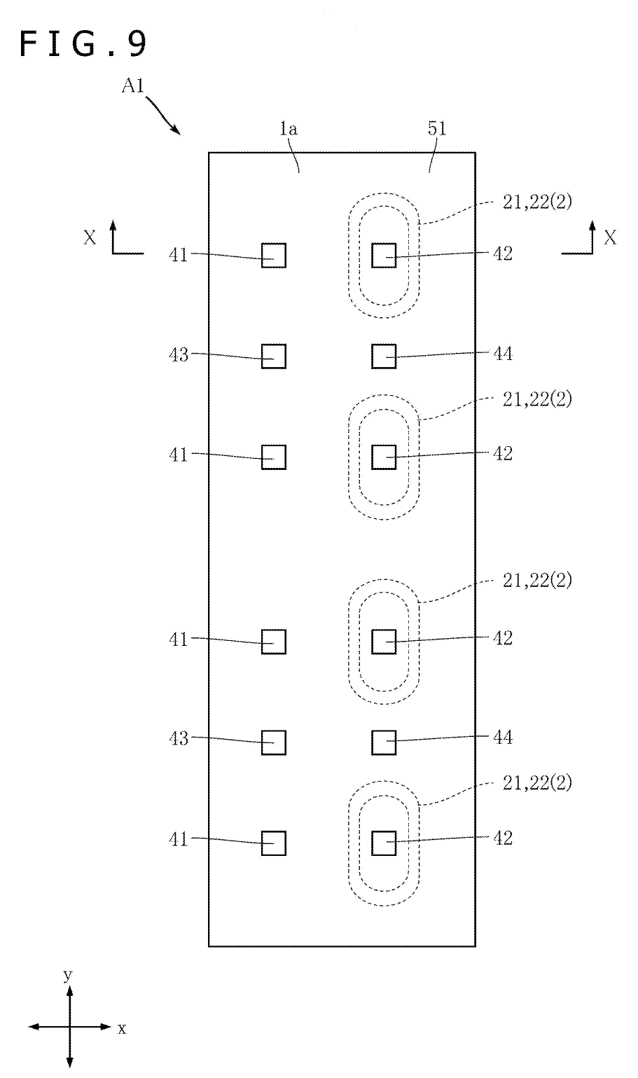

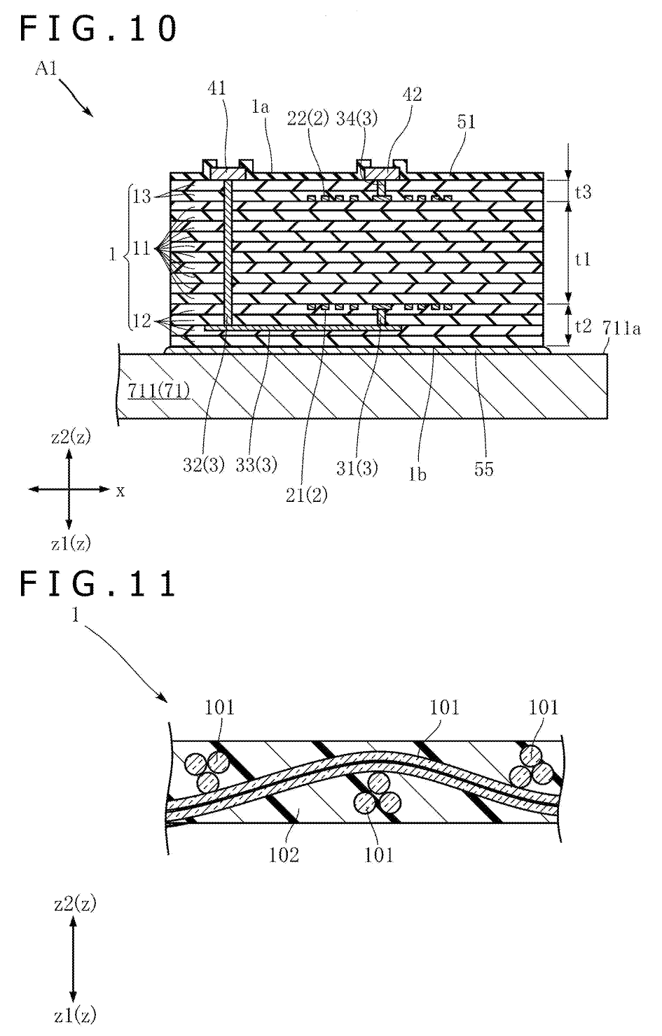

The magnetic field coupling part 2 may incorporate a plurality of pairs of first and second coils 21 and 22. That is, as depicted in FIG. 9, the insulation signal transmission element A1 may have a plurality of first coils 21 and a plurality of second coils 22. FIGS. 7 and 10 depict one of the pairs of the first and second coils 21 and 22. For example, the plurality of pairs of the first and second coils 21 and 22 are arrayed in a longitudinal direction (second direction y) of the insulation signal transmission element A1. The first and second coils 21 and 22 in one pair are separated from each other in the thickness direction z and face each other in the thickness direction z. In this embodiment, the first and second coils 21 and 22 in one pair are planarly coiled each. The first and second coils 21 and 22 in each pair are magnetically connected with each other. The first semiconductor element 61 and the second semiconductor element 62 place the first and second coils 21 and 22 in each pair into magnetic field coupling for electric signal transmission in the insulated state. For example, the first and second coils 21 and 22 may each include a metal such as copper (Cu), nickel (Ni), or gold (Au) or an alloy made of such metals.

The plurality of insulation layers 1 are stacked in the thickness direction z. As depicted in FIG. 11, each of the plurality of insulation layers 1 includes glass fibers 101. The plurality of insulation layers 1 each includes resin 102. The glass fibers 101 may constitute a glass fiber cloth having a plurality of glass fibers woven in a matrix pattern. The glass fiber cloth of the glass fibers 101 extends in the first direction x and the second direction y. The resin 102 may be epoxy resin, for example. The plurality of insulation layers 1 may each be a Flame Retardant Type 4 (FR4) layer, for example. Each of the plurality of insulation layers 1 is not limited to any specific thickness and may have a thickness of 80 to 300 µm inclusive, for example.

The plurality of insulation layers 1 include at least one first insulation layer 11. The at least one first insulation layer 11 is interposed between the first coil 21 and the second coil 22 in the thickness direction z. In this example, the plurality of insulation layers 1 include a plurality of first insulation layers 11. In this example, no conductor exists in a region interposed between the first coil 21 and the second coil 22 in the thickness direction z, the region being further surrounded by the first and second coils 21 and 22 when viewed in the thickness direction z. That is, in the region surrounded by the first and second coils 21 and 22 when viewed in the thickness direction z, there is no metal layer or like object constituting wiring, for example, between the first insulation layers 11 adjacent to each other in the thickness direction z. The first insulation layers 11 are joined to one another through a resin component or like material.

In this embodiment, the plurality of insulation layers 1 include at least one second insulation layer 12 positioned on the first side z1 of the thickness direction z with respect to the first coil 21. In this example, the at least one second insulation layer 12 includes a plurality of second insulation layers 12. The first coil 21 is interposed between the first and second insulation layers 11 and 12. In this case, the first coil 21 can be in a state of being embedded in the first insulation layer 11, in the second insulation layer 12, or in both the first and second insulation layers 11 and 12. Which one of these states occurs may depend on the manufacturing processes of the insulation signal transmission elements A1. In the illustrated example, the first coil 21 is embedded in the second insulation layer 12.

The plurality of insulation layers 1 include at least one third insulation layer 13 positioned on the second side z2 of the thickness direction z with respect to the second coil 22. In this example, the at least one third insulation layer 13 includes a plurality of third insulation layers 13. The second coil 22 is interposed between the first and third insulation layers 11 and 13. In this case, the second coil 22 can be in a state of being embedded in the first insulation layer 11, in the third insulation layer 13, or in both the first and third insulation layers 11 and 13. Which one of these states occurs may depend on the manufacturing processes of the insulation signal transmission elements A1. In the illustrated example, the second coil 22 is embedded in the third insulation layer 13.

There are no definite relations between a first thickness t1, which is a total thickness of the plurality of first insulation layers 11 in the thickness direction z; a second thickness t2, which is a total thickness of the at least one second insulation layer 12 in the thickness direction z; and a third thickness t3, which is a total thickness of the at least one third insulation layer 13 in the thickness direction z. In the illustrated example, the first thickness t1 is greater than the second thickness t2 or the third thickness t3.

There are no definite thickness-based relations between each first insulation layer 11, each second insulation layer 12, and each third insulation layer 13 in the thickness direction z. In the illustrated example, each first insulation layer 11, each second insulation layer 12, and each third insulation layer 13 have the same thickness in the thickness direction z. That is, in the illustrated example, the number of the plurality of stacked first insulation layers 11 is larger than the number of the plurality of stacked second insulation layers 12 and larger than the number of the plurality of stacked third insulation layers 13.

As depicted in FIGS. 2, 6, 7, and 10, the insulation signal transmission element A1 has a plurality of first pads 41 and a plurality of second pads 42. The insulation signal transmission element A1 may also have a plurality of third pads 43 and a plurality of fourth pads 44. The plurality of first pads 41, the plurality of second pads 42, the plurality of third pads 43, and the plurality of fourth pads 44 are positioned on the principal surface 61a. As indicated in FIGS. 7 and 9, each first pad 41 conducts to one of the plurality of first coils 21, and each second pad 42 conducts to one of the plurality of second coils 22. Each third pad 43 conducts to one of the plurality of first coils 21, and each fourth pad 44 conducts to one of the plurality of second coils 22. The composition of the plurality of first pads 41, the plurality of third pads 43, and the plurality of fourth pads 44 includes copper (Cu), for example. A metal layer that includes gold (Au), nickel (Ni), or palladium (Pd), for example, may be formed on the surfaces of the plurality of first pads 41, the plurality of third pads 43, and the plurality of fourth pads 44. As depicted in FIGS. 2, 6, 7, and 10, one of the plurality of wires 81 is joined to each of the plurality of first pads 41, and one of the plurality of wires 82 is joined to each of the plurality of second pads 42.

As depicted in FIG. 10, the insulation signal transmission element A1 may have a wiring part 3. The wiring part 3 includes first through-wiring 31, second through-wiring 32, and lead-out wiring 33 electrically interposed between the first coil 21 and the first pad 41. The wiring part 3 may include a metal such as copper (Cu), nickel (Ni), or gold (Au) or an alloy made of such metals.

The first through-wiring 31 is in contact with the first coil 21 and penetrates at least one second insulation layer 12 in the thickness direction z. In this example, the first through-wiring 31 penetrates two second insulation layers 12.

The lead-out wiring 33 is connected to the first side z1 of the first through-wiring 31 in the thickness direction z and extends in a direction intersecting the thickness direction z. The lead-out wiring 33 is interposed between two second insulation layers 12 adjacent to each other in the thickness direction z. In this case, the lead-out wiring 33 can be in a state of being embedded in one of the adjacent second insulation layers 12, in the other second insulation layer 12, or in both of the adjacent second insulation layers 12. Which one of these states occurs may depend on the manufacturing processes of the insulation signal transmission elements A1. In the illustrated example, the lead-out wiring 33 is embedded in the second insulation layer 12 positioned on the first side z1 of the thickness direction z.

The second through-wiring 32 penetrates at least one first insulation layer 11, at least one third insulation layer 13, and at least one second insulation layer 12 in the thickness direction z. The second through-wiring 32 is connected to the first pad 41 and the lead-out wiring 33. In this example, the second through-wiring 32 penetrates all of the plurality of first insulation layers 11, all of the plurality of third insulation layers 13, and some of the plurality of second insulation layers 12.

The wiring part 3 may further include third through-wiring 34. The third through-wiring 34 penetrates at least one third insulation layer 13 in the thickness direction z. In this example, the third through-wiring 34 penetrates two third insulation layers 13. The third through-wiring 34 permits conduction between the second coil 22 and the second pad 42.

The wiring part 3 may also include a seal ring part, which is not depicted. In planar view, the seal ring part is formed along each of the four outer peripheral sides of the insulation signal transmission element A1 in a manner surrounding the outer periphery of a circuit formation region. The seal ring part is made of copper (Cu) or aluminum (Al), for example.

In this embodiment, the wiring part 3 permits conduction between an inner end of the first coil 21 and the first pad 41 and conduction between an outer end of the second coil 22 and the third pad 43. The wiring part 3 further permits conduction between an inner end of the second coil 22 and the second pad 42 and conduction between an outer end of the second coil 22 and the fourth pad 44.

A protective film 51 is stacked on the plurality of insulation layers 1. The protective film 51 has pad openings for exposing the plurality of first pads 41, the plurality of second pads 42, the plurality of third pads 43, and the plurality of fourth pads 44. The protective film 51 may be a resist layer, for example.

In the semiconductor device B1, the second semiconductor element 62 requires a power supply voltage higher than that required of the first semiconductor element 61. For this reason, there occurs a potential difference between the first and second semiconductor elements 61 and 62. A first circuit that includes the first semiconductor element 61 as one of its constituent elements and a second circuit that includes the second semiconductor element 62 as one of its constituent elements are thus insulated from each other by the insulation signal transmission element A1. In addition to the first semiconductor element 61, the first circuit include the lead 71, the plurality of leads 73, the plurality of wires 81, 84, and 86, and a portion of the insulation signal transmission element A1 (e.g., each first pad 41 and each first coil 21) as the constituent elements. In addition to the second semiconductor element 62, the second circuit include the lead 72, the plurality of leads 74, the plurality of wires 82, 85, and 87, and a portion of the insulation signal transmission element A1 (e.g., each second pad 42 and each second coil 22) as the constituent elements. The first and second circuits have potentials relatively different from each other. In the semiconductor device B1, the second circuit has a potential higher than that of the first circuit. In this state, the insulation signal transmission element A1 relays mutual signals between the first and second circuits. For example, in an inverter device of an electric vehicle or a hybrid electric vehicle, the voltage applied to the ground of the first semiconductor element 61 is approximately 0 V, whereas the voltage applied to the ground of the second semiconductor element 62 can transiently amount to 600 V or higher. Depending on invert device specifications, the voltage applied to the ground of the second semiconductor element 62 can reach 3,750 V or higher.

The semiconductor device B1 may include the conductive support 7. The conductive support 7 constitutes a conduction path between the plurality of insulation signal transmission elements A1, the first semiconductor element 61, and the second semiconductor element 62 on one hand and a wiring substrate on which the semiconductor device B1 is mounted on the other hand. For example, the conductive support 7 is provided by a single lead frame. The lead frame may include copper, a copper alloy, or some other metallic material, for example. The conductive support 7 has the leads 71 and 72, the plurality of leads 73, and the plurality of leads 74.

As indicated in FIGS. 1 and 2, the leads 71 and 72 are positioned separate from each other in the first direction x. In the semiconductor device B1, the insulation signal transmission element A1 and the first semiconductor element 61 are mounted on the lead 71, and the second semiconductor element 62 is mounted on the lead 72.

As depicted in FIG. 2, the lead 71 includes the island part 711 and two terminal parts 712.

As depicted in FIGS. 6 and 7, the island part 711 has the mounting surface 711a facing the second side z2 of the thickness direction z. As indicated in FIGS. 7 and 10, the insulation signal transmission element A1 is joined to the mounting surface 711a via a joining material 55, and the first semiconductor element 61 is also joined to the mounting surface 711a via a conductive joining material 619. The conductive joining material 619 is, for example, solder, metal paste, or a sintered metal. The joining material 55 may be solder, metal paste, a sintered metal, or an insulating adhesive, for example. The island part 711 is covered by the sealing resin 9. In the illustrated example, the island part 711 is rectangular in planar view. The island part 711 has a thickness of 100 to 300 µm inclusive, for example.

As depicted in FIGS. 2, 6, and 7, a plurality of through-holes 713 are formed in the island part 711. Each of the plurality of through-holes 713 penetrates the island part 711 in the thickness direction z and extends in the second direction y. In planar view, at least one of the plurality of through-holes 713 is interposed between the insulation signal transmission element A1 and the first semiconductor element 61. The plurality of through-holes 713 are arrayed in the second direction y. Unlike in the illustrated example, the plurality of through-holes 713 may not be formed in the island part 711.

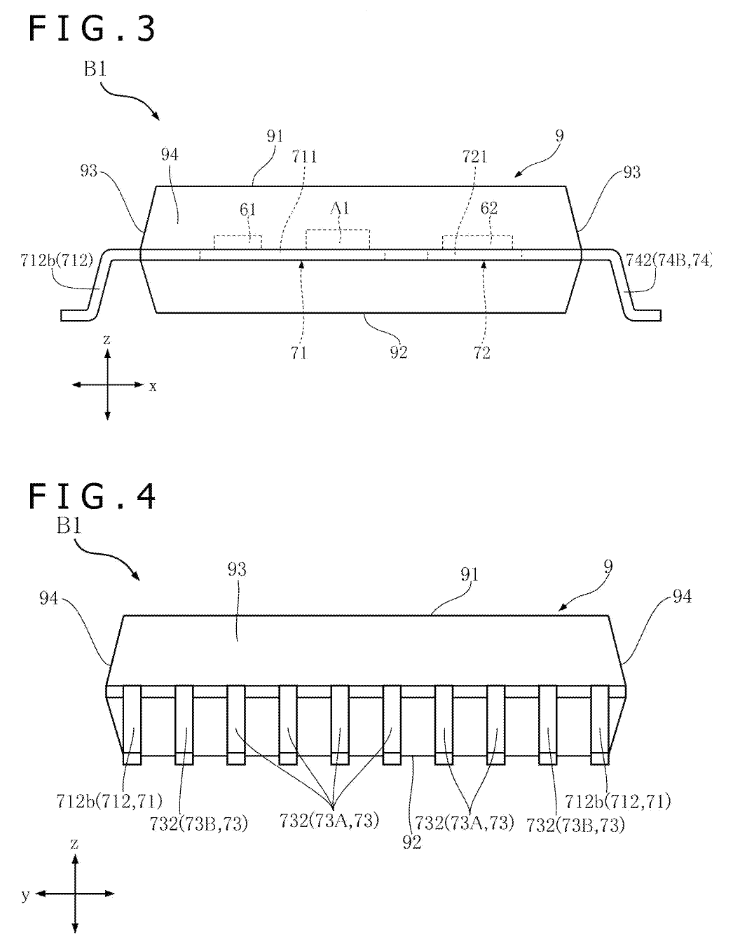

As depicted in FIG. 2, the two terminal parts 712 extend from both sides of the island part 711 in the second direction y. The two terminal parts 712 are positioned separate from each other in the second direction y. At least one of the two terminal parts 712 conducts to the ground of the first semiconductor element 61 via one of the plurality of wires 86. Each of the two terminal parts 712 has a covered part 712a and an exposed part 712b. The covered part 712a is joined to the island part 711 and covered by the sealing resin 9. The exposed part 712b is joined to the covered part 712a and exposed from the sealing resin 9. In planar view, the exposed part 712b extends in the first direction x. As depicted in FIG. 3, the exposed part 712b is bent in gull-wing fashion when viewed in the second direction y. The surface of the exposed part 712b may be plated with tin (Sn), for example.

As depicted in FIG. 2, the lead 72 has the island part 721 and two terminal parts 722.

As indicated in FIGS. 6 and 7, the island part 721 has the mounting surface 721a facing the second side z2 of the thickness direction z. As depicted in FIG. 7, the second semiconductor element 62 is joined to the mounting surface 721a via a conductive bonding material 629. Conductive bonding materials 129 and 149 are each solder, metal paste, or a sintered metal, for example. The island part 721 is covered by the sealing resin 9. In the illustrated example, the island part 721 is rectangular in planar view. As with the island part 711, the island part 721 has a thickness of 100 to 300 µm inclusive, for example.

As depicted in FIG. 2, the two terminal parts 722 extend from both sides of the island part 721 in the second direction y. The two terminal parts 722 are positioned separate from each other in the second direction y. At least one of the two terminal parts 722 conducts to the ground of the second semiconductor element 62 via one of the plurality of wires 87. Each of the two terminal parts 722 has a covered part 722a and an exposed part 722b. The covered part 722a is joined to the island part 721 and covered by the sealing resin 9. The exposed part 722b is joined to the covered part 722a and exposed from the sealing resin 9. In planar view, the exposed part 722b extends in the first direction x. As depicted in FIG. 3, the exposed part 722b is bent in gull-wing fashion when viewed in the second direction y. The surface of the exposed part 722b may be plated with tin, for example.

As depicted in FIGS. 1 and 2, the plurality of leads 73 are positioned opposite to the island part 721 of the lead 72 with respect to the island part 711 of the lead 71 in the first direction x. The plurality of leads 73 are arrayed in the second direction y. At least one of the plurality of leads 73 conducts to the first semiconductor element 61 via one of the plurality of wires 88. The plurality of leads 73 include a plurality of (6 in the illustrated example) intermediate leads 73A and two lateral leads 73B. The two lateral leads 73B are positioned separately on both sides of the plurality of intermediate leads 73A in the second direction y. Each of the two lateral leads 73B is interposed, in the second direction y, between one of the two terminal parts 712 of the lead 71 on one hand and the intermediate lead 73A closest to that terminal part 712 on the other hand.

As depicted in FIGS. 2 and 6, the plurality of leads 73 (the plurality of intermediate leads 73A and the two lateral leads 73B) each have a covered part 731 and an exposed part 732. The covered part 731 is covered by the sealing resin 9. In the illustrated example, the size in the first direction x of each covered part 731 of the two lateral leads 73B is greater than the size in the first direction x of each covered part 731 of the plurality of intermediate leads 73A. As indicated in FIGS. 2 and 6, the exposed part 732 is joined to the covered part 731 and exposed from the sealing resin 9. In planar view, the exposed part 732 extends in the first direction x. As can be seen in FIGS. 2 through 4, the exposed part 732 is bent in gull-wing fashion when viewed in the second direction y. The shape of the exposed part 732 is substantially the same as that of the exposed part 712b of each terminal part 712 of the lead 71. The surface of the exposed part 732 may be plated with tin, for example.

The shape, arrangement, and number of the plurality of leads 73 are not limited to those in the illustrated example. For example, there may be more or fewer leads 73 than those (8 leads) in the illustrated example. Also, some of the plurality of leads 73 may be arranged outward of one of the two terminal parts 712 of the lead 71, for example.

As indicated in FIGS. 1 and 2, the plurality of leads 74 are positioned opposite to the plurality of leads 73 with respect to the island part 711 of the lead 71 in the first direction x. The plurality of leads 74 are arrayed in the second direction y. At least one of the plurality of leads 74 conducts to the second semiconductor element 62 via one of the plurality of wires 85. The plurality of leads 74 include a plurality of (6 in the illustrated example) intermediate leads 74A and two lateral leads 74B. The two lateral leads 74B are positioned separately on both sides of the plurality of intermediate leads 74A in the second direction y. One of the two terminal parts 722 of the lead 72 is interposed, in the second direction y, between one of the two lateral leads 74B on one hand and the intermediate lead 74A closest to that lateral lead 74B on the other hand.

As depicted in FIGS. 2 and 6, the plurality of leads 74 (the plurality of intermediate leads 74A and the two lateral leads 74B) each have a covered part 741 and an exposed part 742. The covered part 741 is covered by the sealing resin 9. In the illustrated example, the size in the first direction x of each covered part 741 of the two lateral leads 74B is greater than the size in the first direction x of each covered part 741 of the plurality of intermediate leads 74A. As depicted in FIGS. 2 and 6, the exposed part 742 is joined to the covered part 741 and exposed from the sealing resin 9. In planar view, the exposed part 742 extends in the first direction x. As can be seen in FIGS. 2, 3, and 5, the exposed part 742 is bent in gull-wing fashion when viewed in the second direction y. The shape of the exposed part 742 is substantially the same as that of each exposed part 722b of the two terminal parts 722 of the lead 72. The surface of the exposed part 742 may be plated with tin, for example.

The shape, arrangement, and number of the plurality of leads 74 are not limited to those in the illustrated example. For example, there may be more or fewer leads 74 than those (8 leads) in the illustrated example. Also, each of the two lateral leads 74B may be interposed, in the second direction y, between one of the two terminal parts 722 of the lead 72 on one hand and the intermediate lead 74A positioned closest to that terminal part 722 on the other hand, for example.

Each of the plurality of connection members 8 permits conduction between two separate parts. As discussed above, the plurality of connection members 8 include the plurality of wires 81, 82, and 84 through 87. Instead of the plurality of wires 81, 82, and 84 through 87 (bonding wires), the plurality of connection members 8 may alternatively be bonding ribbons or plate-like metal members.

The plurality of wires 81, 82, and 84 through 87 each include a metallic material, which is copper or a copper alloy (e.g., a palladium copper alloy). That is, the plurality of wires 81, 82, and 84 through 87 are each a copper wire. Each of the plurality of wires 81, 82, and 84 through 87 may include a core material (that includes copper, for example) and a surface layer part (e.g., palladium) that covers the core material. In this embodiment, the plurality of wires 81, 82, and 84 through 87 may include gold, aluminum, or silver, instead of copper or a copper alloy, as the metallic material.

As depicted in FIGS. 2 and 7, each of the plurality of wires 81 is joined to one of the plurality of first pads 41 of the insulation signal transmission element A1 and to one of the plurality of pads 611 of the first semiconductor element 61. Each wire 81 permits conduction between the insulation signal transmission element A1 and the first semiconductor element 61. The plurality of wires 81 are arrayed in the second direction y.

As depicted in FIGS. 2 and 7, each of the plurality of wires 82 is joined to one of the plurality of second pads 42 of the insulation signal transmission element A1 and to one of the plurality of pads 621 of the second semiconductor element 62. Each wire 82 permits conduction between the insulation signal transmission element A1 and the second semiconductor element 62. The plurality of wires 82 are arrayed in the second direction y. In planar view, each of the plurality of wires 82 straddles the island part 711 of the lead 71 and the island part 721 of the lead 72.

As depicted in FIG. 2, each of the plurality of wires 84 is joined to one of the plurality of pads 611 of the first semiconductor element 61 and to one of the covered parts 731 of the plurality of leads 73. Each wire 84 permits conduction between the first semiconductor element 61 and one of the plurality of leads 73.

As indicated in FIG. 2, each of the plurality of wires 85 is joined to one of the plurality of pads 621 of the second semiconductor element 62 and to one of the covered parts 741 of the plurality of leads 74. Each wire 85 permits conduction between the second semiconductor element 62 and one of the plurality of leads 74.

As depicted in FIG. 2, each of the plurality of wires 86 is joined to one of the plurality of pads 611 of the first semiconductor element 61 and to one of the covered parts 712a of the two terminal parts 712. Each of the plurality of wires 86 permits conduction between the first semiconductor element 61 and the lead 71. It is to be noted that there may be a single wire 86 instead of the plurality of wires 86.

As depicted in FIG. 2, each of the plurality of wires 87 is joined to one of the plurality of pads 621 of the second semiconductor element 62 and to one of the covered parts 722a of the two terminal parts 722. Each of the plurality of wires 87 permits conduction between the second semiconductor element 62 and the lead 72. There may be a single wire 87 instead of the plurality of wires 87.

As depicted in FIG. 1, the sealing resin 9 covers the insulation signal transmission element A1, the first and second semiconductor elements 61 and 62, a portion of the conductive support 7, and the plurality of connection members 8. The sealing resin 9 has an electrical insulation property. The sealing resin 9 insulates the constituent elements of the first circuit (e.g., the lead 71) and those of the second circuit (e.g., the lead 72) from one another. For example, the sealing resin 9 is made of a material that contains black epoxy resin. In the illustrated example, the sealing resin 9 is rectangular in planar view.

As indicated in FIGS. 2 through 5, the sealing resin 9 has a top surface 91, a base end surface 92, paired side surfaces 93, and paired side surfaces 94.

As depicted in FIGS. 3 through 5, the top surface 91 and the base end surface 92 are positioned separate from each other in the thickness direction z. The top surface 91 and the base end surface 92 face the opposite sides in the thickness direction z. The top surface 91 and the base end surface 92 are each substantially flat in shape.

As depicted in FIGS. 3 through 5, the paired side surfaces 93 are joined to the top surface 91 and the base end surface 92 and are positioned separate from each other in the first direction x. Each exposed part 712b of the two terminal parts 712 (lead 71) and each exposed part 732 of the plurality of leads 73 are exposed from one of the paired side surfaces 93 that is positioned on one side of the first direction x. Each exposed part 722b of the two terminal parts 722 (lead 72) and each exposed part 742 of the plurality of leads 74 are exposed from the other of the paired side surfaces 93 that is positioned on the other side of the first direction x.

As depicted in FIGS. 3 through 5, the paired side surfaces 94 are joined to the top surface 91 and the base end surface 92 and are positioned separate from each other in the second direction y. As indicated in FIG. 1, the leads 71 and 72, the plurality of leads 73, and the plurality of leads 74 are positioned away from the paired side surfaces 94.

The use of the semiconductor device B1 is not limited to anything specific. For example, the semiconductor device B1 is used in an inverter device of an electric vehicle. In a motor driver circuit of the inverter device, it is common practice to configure a half-bridge circuit that includes a low-side (low-potential side) switching element and a high-side (high-potential side) switching element. The description that follows will discuss the case where these switching elements are MOSFETs.

In the low-side switching element, the reference potential for the source of the switching element and the gate driver that drives the switching element is ground. In the high-side switching element, on the other hand, the reference potential for the source of the switching element and the gate driver that drives the switching element is equivalent to the potential at the output node of the half-bridge circuit.

Since the potential at the output node varies with the driving of the high- and low-side switching elements, the reference potential for the gate driver that drives the high-side switching element changes accordingly. In a case where the high-side switching element is ON, the reference potential becomes equivalent to the voltage applied to the drain of the high-side switching element (e.g., 600 V or higher). The semiconductor device B1 is configured in such a manner that the ground of the first semiconductor element 61 and that of the second semiconductor element 62 are separated from each other. Thus, in a case where the semiconductor device B1 is used as the gate driver that drives the high-side switching element, a voltage equivalent to the voltage applied to the drain of the high-side switching element is applied transiently to the ground of the second semiconductor element 62.

What follows is an explanation of the workings of the insulation signal transmission element A1 and the semiconductor device B1.

As depicted in FIG. 11, each of the at least one insulation layer 1 includes the glass fibers 101. The shape and rigidity of the at least one insulation layer 1 are thus secured by the glass fibers 101. This makes it possible to reduce the warpage of the at least one insulation layer 1. Meanwhile, the glass fibers 101 may provide high electrical insulation. The insulation signal transmission element A1 can thus improve withstand voltage more appropriately.

The at least one insulation layer 1 further includes the resin 102. This enables the at least one insulation layer 1 to improve the electrical insulation property. It is also possible to permit more appropriate joining to the wiring part 3 and other parts. The insulation layer 1 that includes the glass fibers 101 and the resin 102 has a structure similar to that of a glass epoxy resin substrate material exemplified by FR4, for example. The structure is suitable for ensuring the electrical insulation property and reducing the deformation such as warpage.

The at least one insulation layer 11 includes a plurality of first insulation layers 11. This makes it possible to set as desired the distance between the first and second coils 21 and 22, i.e., the magnitude of the first thickness t1.

There is no conductor in a region interposed between the first and second coils 21 and 22 in the thickness direction z, the region being further surrounded by the first and second coils 21 and 22 when viewed in the thickness direction z. The conductor-free region makes it possible to achieve magnetic field coupling more reliably between the first and second coils 21 and 22.

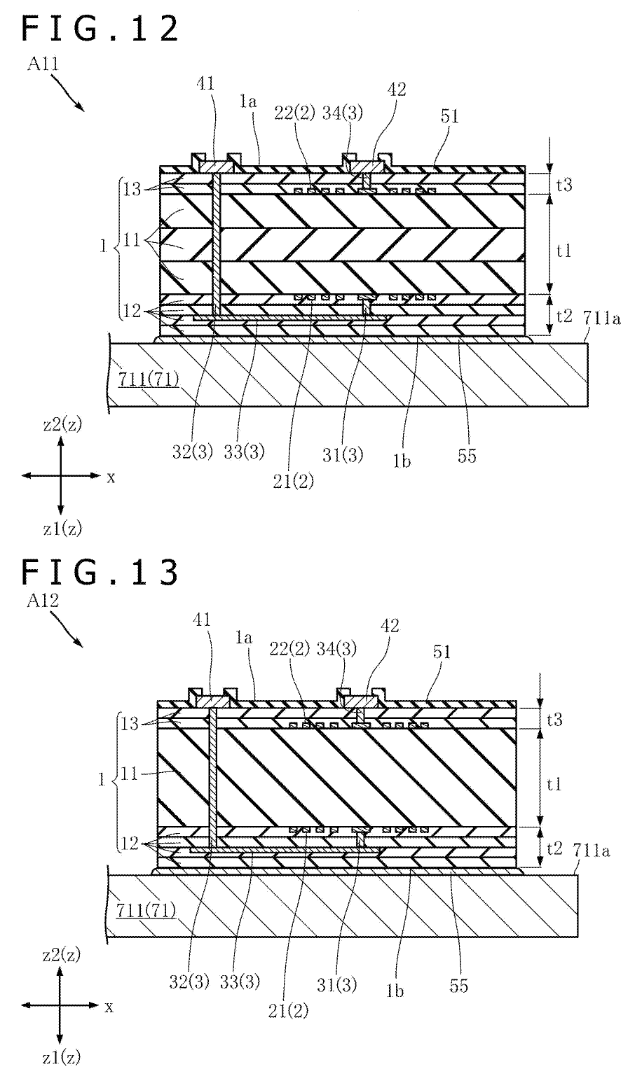

FIGS. 12 through 15 depict other embodiments or modifications of the present disclosure. In these drawings, the constituent elements identical or similar to those of the above-described embodiment are designated by the same reference signs. The configurations of the parts in the embodiments or modifications may be combined as desired, provided there occurs no technical conflict therebetween.

FIG. 12 depicts a first modification of the insulation signal transmission element A1. In an insulation signal transmission element A11 as the first modification, the thickness in the thickness direction z of each first insulation layer 11 is greater than the thickness in the thickness direction z of each second insulation layer 12 and greater than the thickness in the thickness direction z of each third insulation layer 13.

The number of a plurality of stacked first insulation layers 11 in the insulation signal transmission element A11 is smaller than the number of the plurality of stacked first insulation layers 11 in the insulation signal transmission element A1. In the illustrated example, the number of the plurality of stacked first insulation layers 11 is smaller than the number of the plurality of stacked second insulation layers 12. It is to be noted, however, that the relations between the first thickness t1, the second thickness t2, and the third thickness t3 are similar to the relations between the thicknesses in the insulation signal transmission element A1, for example.

According to the first modification, it is possible to increase the withstand voltage more appropriately. The greater thickness of each first insulation layer 11 permits reduction of the number of the plurality of stacked first insulation layers 11 required to obtain the same first thickness t1. This makes it possible to inhibit more reliably the distortion and warpage of the insulation signal transmission element A11.

FIG. 13 depicts a second modification of the insulation signal transmission element A1. In an insulation signal transmission element A12 as the second modification, the at least one first insulation layer 11 includes only one first insulation layer 11. That is, only one insulation layer 11 exits between the first coil 21 and the second coil 22. The thickness of the first insulation layer 11 in the thickness direction z is the same as the first thickness t1.

According to the second modification, it is also possible to increase the withstand voltage more appropriately. The fact that there is only one first insulation layer 11 reliably eliminates concerns associated with an increasing number of the insulation layers.

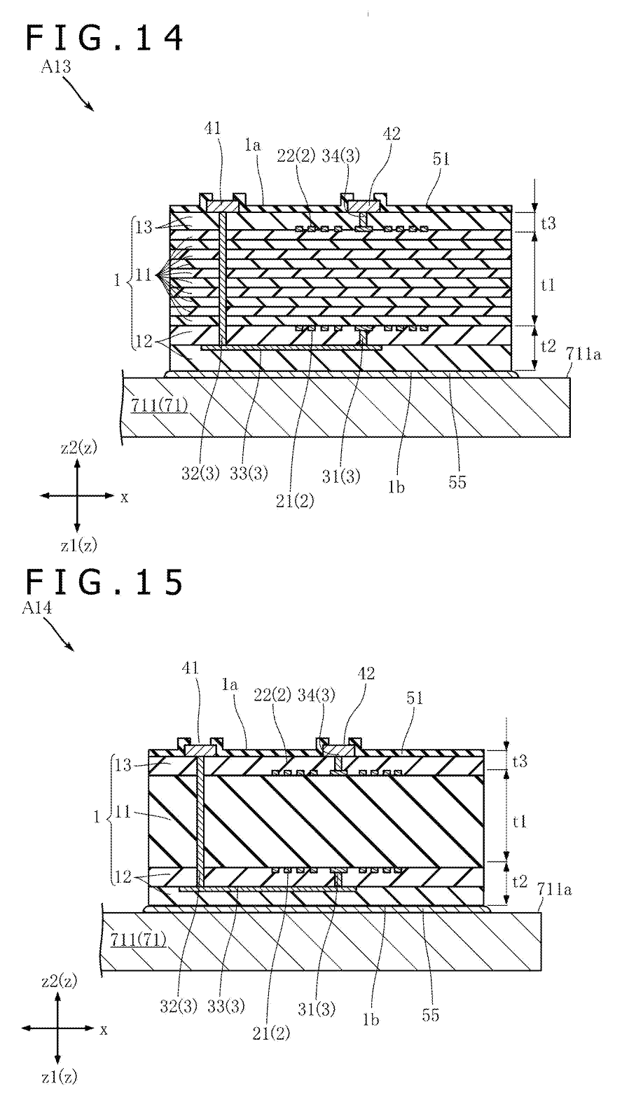

FIG. 14 depicts a third modification of the insulation signal transmission element A1. In an insulation signal transmission element A13 as the third modification, the thickness in the thickness direction z of each second insulation layer 12 and of each third insulation layer 13 is greater than the thickness in the thickness direction z of each first insulation layer 11. The at least one second insulation layer 12 includes only two second insulation layers 12. The lead-out wiring 33 is interposed between the two second insulation layers 12. The at least one third insulation layer 13 includes only one third insulation layer 13.

According to the third modification, it is also possible to increase the withstand voltage more appropriately. The reduced number of the stacked at least one second insulation layer 12 and that of the stacked at least one third insulation layer 13 reliably eliminate concerns associated with an increasing number of the insulation layers.

FIG. 15 depicts a fourth modification of the insulation signal transmission element A1. In an insulation signal transmission element A14 as the fourth modification, the at least one first insulation layer 11 includes only one first insulation layer 11. The at least one second insulation layer 12 includes only two second insulation layers 12. The at least one third insulation layer 13 includes only one third insulation layer 13.

According to the fourth modification, it is also possible to increase the withstand voltage more appropriately. The fourth modification further simplifies the manufacturing processes of the insulation signal transmission element A14.

The insulation signal transmission element and the semiconductor device according to the present disclosure are not limited to the embodiments and modifications discussed above. The specific configurations of each of the parts constituting the insulation signal transmission element and the semiconductor device of this disclosure may be varied in design as desired.

The present disclosure contains subject matter related to that disclosed in Japanese Priority Patent Application JP 2025-010326 filed in the Japan Patent Office on January 24, 2025, the entire content of which is hereby incorporated by reference.

### Supplement 1

An insulation signal transmission element (A1) including:

a plurality of insulation layers (1) stacked in a thickness direction (z); and

a magnetic field (2) coupling part including a first coil (21) positioned on a first side (z1) of the thickness direction (z) and a second coil (22) positioned on a second side (z2) of the thickness direction (z),

in which the plurality of insulation layers (1) include at least one first insulation layer (11) interposed between the first coil (21) and the second coil (22) in the thickness direction (z), and

each of the insulation layers includes glass fibers (101).

### Supplement 1-1

The insulation signal transmission element (A1) according to supplement 1, the plurality of insulation layers (1) each include resin (102).

### Supplement 2

The insulation signal transmission element (A1) according to supplement 1, in which the plurality of insulation layers (1) include at least one second insulation layer (12) positioned on the first side (z1) of the thickness direction (z) with respect to the first coil (21).

### Supplement 3

The insulation signal transmission element (A1) according to supplement 2, in which the plurality of insulation layers (1) include at least one third insulation layer (13) positioned on the second side (z2) of the thickness direction (z) with respect to the second coil (22).

### Supplement 4

The insulation signal transmission element (A1) according to supplement 3, further including:

a first pad (41) positioned on the second side (z2) of the thickness direction (z) with respect to the at least one third insulation layer (13), the first pad (41) conducting to the first coil (21).

### Supplement 5

The insulation signal transmission element (A1) according to supplement 4, further including:

a second pad (42) positioned on the second side (z2) of the thickness direction (z) with respect to the at least one third insulation layer (13), the second pad (42) conduction to the second coil (22).

### Supplement 6

The insulation signal transmission element (A1) according to supplement

5, further including:

a wiring part (3) that includes first through-wiring (31), second through-wiring (32), and lead-out wiring (33) electrically interposed between the first coil (21) and the first pad (41),

in which the first through-wiring (31) is in contact with the first coil (21) and penetrates at least one semiconductor element (12) in the thickness direction (z),

the lead-out wiring (33) is connected to the first side (z1) of the thickness direction (z) of the first through-wiring (31), the lead-out wiring (33) further extending in a direction intersecting the thickness direction (z), and

the second through-wiring (32) penetrates the at least one first insulation layer (11), the at least one third insulation layer (13), and the at least one semiconductor element (12) in the thickness direction (z), the second through-wiring (32) being further connected to the first pad (41) and the lead-out wiring (33).

### Supplement 7

The insulation signal transmission element (A1) according to supplement

6, in which the wiring part (3) further includes third through-wiring (34) that penetrates the at least one third insulation layer (13) in the thickness direction (z) and permits conduction between the second coil (22) and the second pad (42).

### Supplement 8

The insulation signal transmission element (A1) according to any one of supplements 3 through 7, in which the plurality of insulation layers (1) include a plurality of the first insulation layers (11).

### Supplement 9

The insulation signal transmission element (A1) according to supplement 8, in which a total thickness of the plurality of the first insulation layers (11) in the thickness direction (z) is greater than a total thickness of the at least one second insulation layer (12) in the thickness direction (z) and greater than a total thickness of the at least one semiconductor element (13) in the thickness direction (z).

### Supplement 10

The insulation signal transmission element (A1) according to supplement 9, in which a thickness of each of the first insulation layers (11) in the thickness direction (z), a thickness of each of the second insulation layers (12) in the thickness direction (z), and a thickness of each of the semiconductor elements (13) in the thickness direction (z) are the same.

### Supplement 11

The insulation signal transmission element (A12) according to any one of supplements 3 through 7, in which the at least one insulation layer (1) includes the only one first insulation layer (11).

### Supplement 12

The insulation signal transmission element (A1) according to supplement 11, in which a thickness of the one first insulation layer (11) in the thickness direction (z) is greater than a thickness of each of the at least one second insulation layer (12) in the thickness direction (z) and greater than a thickness of each of the at least one third insulation layer (13) in the thickness direction (z).

### Supplement 13

The insulation signal transmission element (A1) according to any one of supplements 1 through 12, in which there is no conductor in a region interposed between the first coil (21) and the second coil (22) in the thickness direction (z), the region being further surrounded by the first coil (21) and the second coil (22) when viewed in the thickness direction (z).

### Supplement 14

The insulation signal transmission element (A1) according to any one of supplements 3 through 13, in which the at least one second insulation layer (12) includes a plurality of the second insulation layers (12).

### Supplement 14-1

The insulation signal transmission element (A13) according to any one of supplements 3 through 13, in which the at least one second insulation layer (12) includes the only two second insulation layers (12).

### Supplement 15

The insulation signal transmission element (A1) according to any one of supplements 3 through 14, in which the at least one third insulation layer (13) includes a plurality of the third insulation layers (13).

### Supplement 15-1

The insulation signal transmission element (A13) according to any one of supplements 3 through 13, in which the at least one third insulation layer (13) includes the only one third insulation layer (13).

### Supplement 16

A semiconductor device including:

the insulation signal transmission element (A1) according to any one of supplements 3 through 15;

a first semiconductor element (61) conducting to the first coil (21); and

a second semiconductor element (62) conducting to the second coil (22).

What is claimed is:

1. An insulation signal transmission element comprising:
a plurality of insulation layers stacked in a thickness direction; and
a magnetic field coupling part including a first coil positioned on a first side of the thickness direction and a second coil positioned on a second side of the thickness direction,
wherein the plurality of insulation layers include at least one first insulation layer interposed between the first coil and the second coil in the thickness direction, and
each of the insulation layers includes glass fibers.

2. The insulation signal transmission element according to claim 1, wherein the plurality of insulation layers include at least one second insulation layer positioned on the first side of the thickness direction with respect to the first coil.

3. The insulation signal transmission element according to claim 2, wherein the plurality of insulation layers include at least one third insulation layer positioned on the second side of the thickness direction with respect to the second coil.

4. The insulation signal transmission element according to claim 3, further comprising:
a first pad positioned on the second side of the thickness direction with respect to the at least one third insulation layer, the first pad conducting to the first coil.

5. The insulation signal transmission element according to claim 4, further comprising:
a second pad positioned on the second side of the thickness direction with respect to the at least one third insulation layer, the second pad conducting to the second coil.

6. The insulation signal transmission element according to claim 5, further comprising:
a wiring part that includes first through-wiring, second through-wiring, and lead-out wiring electrically interposed between the first coil and the first pad,
wherein the first through-wiring is in contact with the first coil and penetrates at least one semiconductor element in the thickness direction,
the lead-out wiring is connected to the first side of the thickness direction of the first through-wiring, the lead-out wiring further extending in a direction intersecting the thickness direction, and
the second through-wiring penetrates the at least one first insulation layer, the at least one third insulation layer, and the at least one semiconductor element in the thickness direction, the second through-wiring being further connected to the first pad and the lead-out wiring.

7. The insulation signal transmission element according to claim 6, wherein the wiring part further includes third through-wiring that penetrates the at least one third insulation layer in the thickness direction and permits conduction between the second coil and the second pad.

8. The insulation signal transmission element according to claim 3, wherein the plurality of insulation layers include a plurality of the first insulation layers.

9. The insulation signal transmission element according to claim 8, wherein a total thickness of the plurality of the first insulation layers in the thickness direction is greater than a total thickness of the at least one second insulation layer in the thickness direction and greater than a total thickness of the at least one semiconductor element in the thickness direction.

10. The insulation signal transmission element according to claim 9, wherein a thickness of each of the first insulation layers in the thickness direction, a thickness of each of the second insulation layers in the thickness direction, and a thickness of each of the semiconductor elements in the thickness direction are the same.

11. The insulation signal transmission element according to claim 3, wherein the at least one insulation layer includes the only one first insulation layer.

12. The insulation signal transmission element according to claim 11, wherein a thickness of the one first insulation layer in the thickness direction is greater than a thickness of each of the at least one second insulation layer in the thickness direction and greater than a thickness of each of the at least one third insulation layer in the thickness direction.

13. The insulation signal transmission element according to claim 1, wherein there is no conductor in a region interposed between the first coil and the second coil in the thickness direction, the region being further surrounded by the first coil and the second coil when viewed in the thickness direction.

14. The insulation signal transmission element according to claim 3, wherein the at least one second insulation layer includes a plurality of the second insulation layers.

15. The insulation signal transmission element according to claim 3, wherein the at least one third insulation layer includes a plurality of the third insulation layers.

16. A semiconductor device comprising:
the insulation signal transmission element according to claim 1;
a first semiconductor element conducting to the first coil; and
a second semiconductor element conducting to the second coil.
